(19) United States
(12) Patent Application Publication
(10) Pub. No.: US 2008/0094148 A1
(43) Pub. Date: Apr. 24, 2008

(54) OSCILLATION CIRCUIT

(75) Inventor: Teruo TAKIZAWA, Matsumoto-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 11/847,916

(22) Filed: Aug. 30, 2007

(30) Foreign Application Priority Data
Oct. 20, 2006 (JP) 2006-286165

(51) Int. Cl. H03B 5/30

(52) U.S. Cl. 331/116 FE

(57) ABSTRACT

An oscillation circuit includes: an inverter circuit that is composed of at least one pair of transistors including an n-type transistor and a p-type transistor, the inverter circuit being formed in a single crystal semiconductor layer deposited on an insulator; a gate terminal capacitance whose one end is connected to an input end of the inverter circuit and another end is grounded; a drain terminal capacitance whose one end is connected to an output end of the inverter circuit and the other end is grounded; and a feedback resistance and a resonator that are connected in parallel between the input end and the output end of the inverter circuit, the drain terminal capacitance having a capacitance value that is smaller than the capacitance value of the gate terminal capacitance.

### BACKGROUND OF THE INVENTION

1. Technical Field

Several aspects of the invention relates to a technology to reduce the current consumption in an oscillation circuit that is formed on either an insulating substrate or an insulating layer.

2. Related Art

In recent years, high performance integrated circuits operating with low power consumption and low supply voltage are developed in the semiconductor industry. In particular, it is highly important to reduce the power consumption in oscillation circuits that are used as timing devices including, for example, an oscillation circuit that is provided in a central processing unit (CPU) and produces clock signals, an oscillation circuit that is provided in an integrated circuit (IC) for wireless communication and generates a reference frequency, and an oscillation circuit provided in a timing IC.

These oscillation circuits each include an external resonator having a highly precise characteristic resonant frequency and a circuit for aiding the oscillation, thereby converting the mechanical vibration of the resonator into electrical oscillation signals. For the uses described above, a Colpitts type oscillation circuit is generally used, the oscillation circuit being a combination of a quartz crystal resonator and an inverter circuit. JP-A-10-13155 discloses a Colpitts type oscillation circuit in which the oscillation frequency can be adjusted by means of a variable capacitance element.

However, such an oscillation circuit as described above generally operates at all times in order to generate a reference frequency in a system, thereby raising the level of power consumption of the whole system through the power consumption of the circuit itself. Thus, reduction of power, i.e. current, consumed in an oscillation circuit is a big challenge in realization of lower power consumption in a system.

### SUMMARY

An advantage of the present invention is to provide an oscillation circuit that consumes lower amount of electric current.

An oscillation circuit according to an aspect of the invention includes: an inverter circuit composed of at least one pair of transistors including an n-type transistor and a p-type transistor, the inverter circuit being formed in a single crystal semiconductor layer deposited on an insulator; a gate terminal capacitance whose one end is connected to an input end of the inverter circuit and other end is grounded; a drain terminal capacitance whose one end is connected to an output end of the inverter circuit and other end is grounded; and a feedback resistance and a resonator that are connected in parallel between the input end and the output end of the inverter circuit, the drain terminal capacitance having a capacitance value that is smaller than the capacitance value of the gate terminal capacitance.

Because of the gate terminal capacitance that is made larger than the drain terminal capacitance in the oscillation circuit, the load becomes larger toward the gate as electric current returns from the drain to the gate via the feedback resistance, thereby reducing the amplitude of the gate voltage. This allows the current consumption to be lowered.

In this case, the n-type transistor and the p-type transistor in the oscillation circuit may be field effect transistors.

This permits the current consumption to be reduced in an oscillation circuit using field effect transistors that are formed in a semiconductor layer on an insulator.

In this case, the n-type transistor and the p-type transistor in the oscillation circuit may be thin film transistors (TFTs).

This permits the current consumption to be reduced in an oscillation circuit using TFTs that are formed in a semiconductor layer on an insulating substrate such as a glass or a quartz substrate.

In this case, at least one of the drain terminal capacitance and the gate terminal capacitance in the oscillation circuit may be a voltage variable capacitance.

This allows the current consumption to be controlled because the capacitance value can be varied through control of the voltage applied to the voltage variable capacitance.

### BRIEF DESCRIPTION OF THE DRAWINGS

The invention will be described with reference to the accompanying drawings, wherein like numbers reference like elements.

FIG. 1 is a schematic circuit diagram showing an oscillation circuit according to one embodiment of the invention.

FIG. 2 is a sectional view showing the structure of an inverter circuit formed on a silicon-on-insulator (SOI) substrate in the oscillation circuit according to the embodiment of the invention.

FIG. 3 is a schematic circuit diagram showing an equivalent circuit of the oscillation circuit according to the embodiment of the invention.

FIG. 4 is a schematic showing the current consumption of the oscillation circuit according to the embodiment of the invention, in the case where a drain terminal capacitance and a gate terminal capacitance are varied in the oscillation circuit.

FIGS. 5A, 5B and 5C are wave form charts showing the gate voltage, the drain voltage and the current consumption of the oscillation circuit according to the embodiment of the invention, in the case where the drain terminal capacitance and the gate terminal capacitance are varied in the oscillation circuit.

FIG. 6 is a sectional view showing the structure of an inverter circuit that is formed with TFTs on an insulating substrate of the oscillation circuit according to the embodiment of the invention.

### DESCRIPTION OF EXEMPLARY EMBODIMENTS

Embodiments of the invention will be described.

### First Embodiment

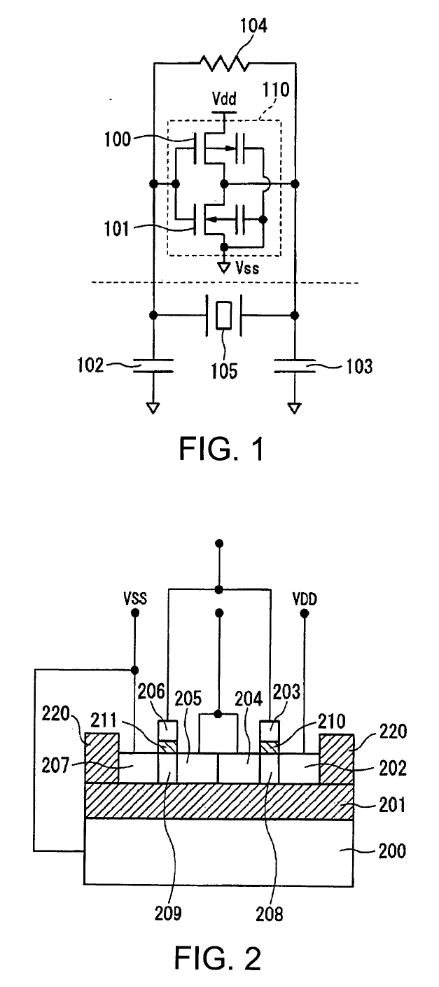

Referring to FIG. 1, an oscillation circuit according to one embodiment of the invention will now be described.

In FIG. 1, 100 is a number representing a p-type transistor, 101 representing an n-type transistor, 102 representing a gate terminal capacitance (Cg), 103 representing a drain terminal capacitance (Cd), 104 representing a feedback resistance (Rf), 105 representing a quartz crystal resonator, and 110 representing an inverter circuit.

The gate electrodes of the p-type transistor 100 and the n-type transistor 101 are commonly connected and the source electrodes of the p-type transistor is connected to a power source (VDD). The drain electrodes of the p-type transistor 100 and the n-type transistor 101 are commonly connected and the source of the n-type transistor 101 is grounded to a VSS. Back gate electrodes of the p-type transistor 100 and the n-type transistor 101 are connected to each other and grounded to the VSS, with each of the back gate electrodes is formed underneath a buried insulating layer on which the corresponding transistors are formed.

The p-type transistor 100 and the n-type transistor 101, being connected in such a manner as described above, form the inverter circuit 110. The commonly connected gates of the p-type transistor 100 and the n-type transistor 101 form an input end of the inverter circuit 110. The commonly connected drains of the p-type transistor 100 and the n-type transistor 101 form an output end of the inverter circuit 110.

The p-type transistor 100 and the r-type transistor 101 are formed on an SOI substrate. The structure of these transistors will be described later.

The quartz crystal resonator 105 is parallel connected between the input end and the output end of the inverter circuit 110. The feedback resistance (Rf) 104 is parallel connected between the input end and the output end of the inverter circuit 110. Furthermore, one end of the gate terminal capacitance (Cg) 102 is connected to the input end of the inverter circuit 110, and the other end thereof is grounded to the VSS. Also, one end of the drain terminal capacitance (Cd) 103 is connected to the output end of the inverter circuit 110, and the other end thereof is grounded to the VSS. The output end of the inverter circuit 110 is the output terminal for oscillation signals. Here, the gate terminal capacitance (Cg) 102 and the drain terminal capacitance (Cd) 103 are distinguished from the internal gate capacitance of the gate electrode and the internal drain capacitance of the drain electrode, the gate electrode and the drain electrode being included in each of the p-type transistor 100 and the n-type transistor 101.

A Colpitts type oscillation circuit is formed by the configuration described above.

Here, the capacitance value of the drain terminal capacitance (Cd) 103 is smaller than the capacitance value of the gate terminal capacitance (Cg) 102. This condition allows the current consumption of the oscillation circuit to be smaller than in the case where: the capacitance value of the drain terminal capacitance (Cd)=the capacitance value of the gate terminal capacitance (Cg). To give an example, the capacitance value of the drain terminal capacitance (Cd) 103 will be 4 pF where the capacitance value of the gate terminal capacitance (Cg) is 12 pF.

Next, referring to FIG. 2, the structure of the above transistors will be described.

In FIG. 2, 200 is a number representing a silicon substrate, 201 representing an insulating layer, 202 representing a p+-type semiconductor region, 203 representing a gate, 204 representing a p+-type semiconductor region, 205 representing an n+-type semiconductor region, 206 representing a gate 207 representing an n+-type semiconductor region, 208 representing an n-type semiconductor region, 209 representing a p-type semiconductor region, 210 and 211 representing oxide films, and 220 representing an element isolation insulating layer.

The insulating layer 201 is formed on the silicon substrate 200. The p+-type semiconductor regions 202 and 204, sandwiching the n-type semiconductor region 208, are formed in a single crystal semiconductor layer deposited on the insulating layer 201. The n+-type semiconductor regions 205 and 207, sandwiching the p-type semiconductor region 209, are formed in a single crystal semiconductor layer deposited on the insulating layer 201. The gate 203 is formed on the n-type semiconductor region 208, with the oxide film 210 inbetween. The gate 206 is formed on the p-type semiconductor region 209, with the oxide film 211 inbetween.

The above-described p+-type semiconductor regions 202 and 204, the n-type semiconductor region 208 and the gate 203 form together the p-type transistor 100 that is a field-effect transistor on an SOI substrate. Furthermore, the above-described n+-type semiconductor regions 205 and 207, the p-type semiconductor region 209 and the gate 206 form together the n-type transistor 101 that is a field-effect transistor on an SOI substrate.

In addition, the p-type transistor 100 and the n-type transistor 101 are isolated by the insulating film 201 that is formed by either local oxidation of silicon (LOCOS) or shallow trench isolation (STI).

The gates 203 and 206 are electrically connected through metal wiring (not shown) while the p+-type semiconductor region 204 and the n+-type semiconductor region 205 are also electrically connected through metal wiring (not shown). The above-described p+-type semiconductor region 204 and n-type semiconductor region 205 may be connected through a silicide thin film of titanium silicide (TiSi2) or cobalt silicide (CoSi2). The p+-type semiconductor region 202 is further connected to the power source (VDD). The n+-type semiconductor region 207 is connected to the silicon substrate 200 while being grounded to the VSS. The above-described connection forms the inverter circuit 110 that has been described with reference to FIG. 1.

Meanwhile, an SOI substrate made by lamination is used in the present embodiment, and the silicon substrate 200 serving as a base has an electric resistivity of 10 to 20 (Ω·cm), to cite a case.

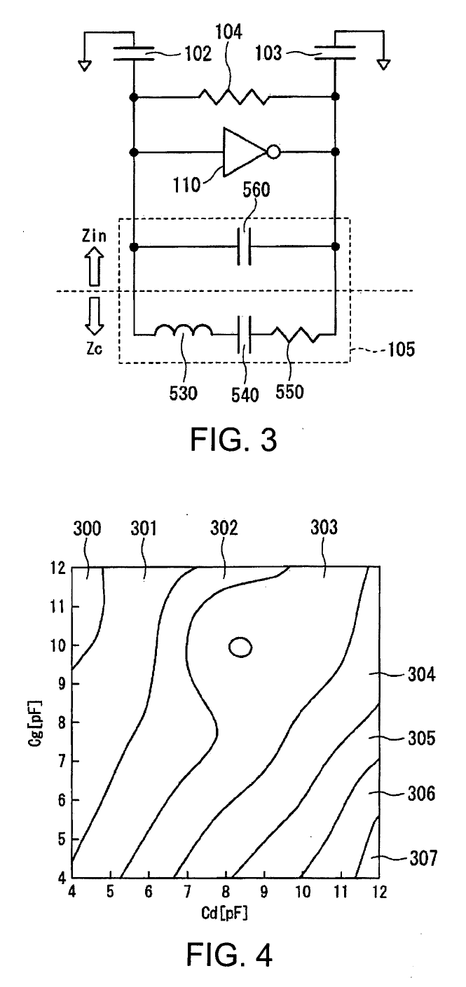

Next, referring to FIG. 3, conditions for the oscillating operation of the Colpitts type oscillation circuit will be described.

FIG. 3 is an equivalent circuit diagram of the Colpitts type oscillation circuit, showing an equivalent circuit that is a substitution for the quartz crystal resonator in the schematic circuit diagram of the oscillation circuit shown in FIG. 1. In the diagram, 530 is a number representing a series inductor (L1), 540 representing a series capacitance (C1) and 550 representing a series resistance (R1). Furthermore, 560 is a number representing a parallel capacitance (C0) of the quartz crystal resonator 105.

The quartz crystal resonator 105 can be equivalently represented by the series inductor (L1) 530, the series capacitance (C1) 540, the series resistance (R1) 550 and the parallel capacitance (C0) 560, as shown in the diagram. The other components are the same as in FIG. 1 and, thus, explanation thereof shall be omitted.

Next, conditions for oscillation of the above oscillation circuit will be described. Here, it is assumed that, in the whole equivalent circuit of the quartz crystal resonator 105, the series circuit portion excluding the parallel capacitance 560 has an impedance of Zc, and the other portion nearer to the inverter circuit, including the parallel capacitance 560, has an impedance of Zin. Then, the impedance Zc of the series circuit can be expressed as: Zc=R1+jωL1+1/(jωC1) (Condition 1). Thus, the real part of the impedance Zc is R1.

In order that the oscillation circuit oscillates, the whole of the oscillation circuit needs to have an impedance of Ztot (—Zin+Zc), the real part of which has a negative value. Using the fact that the real part of the impedance Ze is R1, the conditions for oscillation of the oscillation circuit will be expressed as: Re[Ztot]=Re[Zin+Zc]≈Re[Zin]+R1<0 (Condition 2). Therefore, it is required that the impedance Zin of the portion nearer to the inverter has a real part that is smaller than −R1 (i.e. larger in absolute value).

Here, as the impedance Zin is also a function of the drain terminal capacitance (Cd) 103 and the gate terminal capacitance (Cg) 102, it is required that the capacitance values of the drain terminal capacitance (Cd) 103 and the gate terminal capacitance (Cg) 102 are determined in such a way as to satisfy the Condition 2 described above.

Next, referring to FIG. 4, the current consumption of the oscillation circuit that is configured in accordance with the present embodiment will be described.

FIG. 4 is a diagram showing the current consumption of the oscillation circuit in which the drain terminal capacitance (Cd) and the gate terminal capacitance (Cg) are varied within the range of the above-described Condition 2 regarding oscillation. The diagram shows the results from a simulation that has been performed by the inventors.

In the diagram, the axis of abscissas represents the drain terminal capacitance (Cd) and the axis of ordinate represents the gate terminal capacitance (Cg). The curved patterns in the diagram are iso current consumption lines. The numbers 300 through 307 represent regions showing the dimensions of the current consumption. The dimensions of the current consumption meet the following relationship: Region 300<Region 301<Region 302<Region 303<Region 304<Region 305<Region 306<Region 307. Namely, the current consumption is the smallest in Region 300 and the largest in Region 307.

As shown in FIG. 4, in regions where the drain terminal capacitance (Cd) is smaller than the gate terminal capacitance (Cg), the current consumption of the oscillation circuit is smaller than under the condition where the drain terminal capacitance (Cd) is equal to the gate terminal capacitance (Cg). In the illustrated example, the current consumption of the oscillation circuit is the smallest in Region 300 where the drain terminal capacitance (Cd) is 4 pF and the gate terminal capacitance (Cg) is 12 pF.

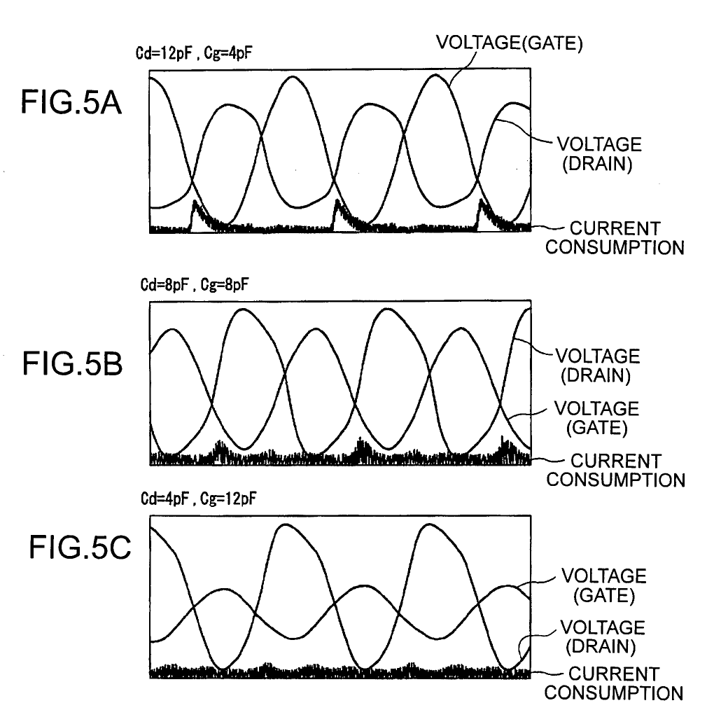

Next, referring to FIGS. 5A, 5B and 5C, the voltage at each portion of the oscillation circuit and wave forms of the current consumption of the circuit, in the case where the drain terminal capacitance and the gate terminal capacitance are varied, will be described.

In the diagrams, the axis of abscissas of each graph represents time while the axis or ordinate thereof represents voltage values and current values, showing the same scale in all the graphs in FIGS. 5A, 5B and 5C. Furthermore, the gate voltage in each graph represents the gate voltage of the p-type transistor 100 and the n-type transistor 101 shown in FIG. 1, whereas the drain voltage represents the drain voltage of the p-type transistor 100 and the n-type transistor 101 shown therein. The current consumed represents the current flowing from the power source (VDD).

FIG. 5A is a wave form chart of the gate voltage, the drain voltage and the current consumption in the case where the drain terminal capacitance (Cd) is 12 pF and the gate terminal capacitance (Cg) is 4 pF. This condition corresponds to the condition of Region 307 in FIG. 4. Under the condition, the amplitude of the gate voltage is larger than the amplitude of the drain voltage and the current consumption is the largest among the illustrated conditions.

FIG. 5B is a wave form chart of the gate voltage, the drain voltage and the current consumption in the case where the drain terminal capacitance (Cd) is 8 pF and the gate terminal capacitance (Cg) is 8 pF. This condition corresponds to the condition of Region 303 in FIG. 4. Under the condition, the amplitude of the gate voltage is approximately equal to the amplitude of the drain voltage.

FIG. 5C is a wave form chart of the gate voltage, the drain voltage and the current consumption in the case where the drain terminal capacitance (Cd) is 4 pF and the gate terminal capacitance (Cg) is 12 pF. This condition corresponds to the condition of Region 300 in FIG. 4. Under the condition, the amplitude of the gate voltage is smaller than the amplitude of the drain voltage, and the current consumption is the smallest among the illustrated conditions.

Next, the oscillating operation of the oscillation circuit will be described in comparing the condition shown in FIG. 5C, where the gate terminal capacitance (Cg) 102 is made larger and the drain terminal capacitance (Cd) 103 smaller, to the condition shown in FIG. 5B, where the two capacitances are equal.

Under the condition shown in FIG. 5C, the gate terminal capacitance (Cg) 102 is larger than under the condition shown in FIG. 5B. This increases the load toward the gate as the current returns from the drain to the gate via the feedback resistance (Rf) 104, thereby decreasing the amplitude of the gate voltage.

Here, in the case of an oscillation circuit using an SOI substrate, the drains of the transistors essentially have smaller parasitic capacitance (capacitance of a buried insulating layer 201) than in the case where a bulk silicon substrate is used (about one third of the former case). This allows the circuit to oscillate even if the driving capacity of the transistors is small.

That means that an oscillation circuit using an SOI substrate permits oscillation with the small driving capacity of the SOI transistors even if the gate terminal capacitance (Cg) 102 is large. Therefore, it enables oscillation under a condition where the capacitance value of the drain terminal capacitance (Cd) is smaller than the capacitance value of the gate terminal capacitance (Cg). This reduces the amplitude of the gate voltage, thereby lowering the current consumption.

Meanwhile, at least one of the drain terminal capacitance (Cd) 103 and the gate terminal capacitance (Cg) 102 may be a voltage variable capacitance. In this case, variation of the capacitance value through control of the voltage applied to the voltage variable capacitance will permit the current consumption to be controlled.

### Second Embodiment

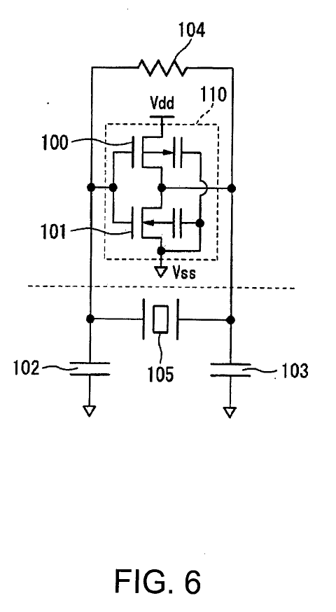

Referring to FIG. 6, a second embodiment of the invention will be described.

In the present embodiment, the transistors in the oscillation circuit described above using FIG. 1 will have a TFT structure.

In FIG. 6, 600 is a number representing a bottom electrode, 601 representing an insulating substrate, 602 representing a p+-type semiconductor region, 603 representing a gate, 604 representing a p+-type semiconductor region, 605 representing an n+-type semiconductor region, 606 representing a gate, 607 representing an n+-type semiconductor region, 608 and 609 representing intrinsic polycrystalline semiconductor regions, and 610 and 611 representing insulating films. As compared to the first embodiment, there is no element isolation insulating film 220 here. This is due to the fact that, in a TFT manufacturing process, element isolation is generally performed through etching of a polycrystalline semiconductor layer.

As to the material of the insulating substrate 601, it is either a glass substrate or a quartz substrate.

The bottom electrode 600 is formed on the undersurface of the insulating substrate 601. The p+-type semiconductor regions 602 and 604 are formed in a single crystal semiconductor layer deposited on the insulating substrate 601, with the intrinsic polycrystalline semiconductor region 608 being sandwiched between the two p+-type regions. The n+-type semiconductor regions 605 and 607 are formed in a single crystal semiconductor region deposited on the insulating substrate 601, with the intrinsic polycrystalline semiconductor region 609 being sandwiched between the twon+-type regions. Furthermore, the gate 603 is formed on the intrinsic polycrystalline semiconductor region 608, with the insulating film 610 inbetween. The gate 606 is formed on the intrinsic polycrystalline semiconductor region 609, with the insulating film 611 inbetween. However, whereas the present embodiment specifies that the polar character of the regions 609 and 608 is an intrinsic semiconductor, the invention is not limited thereto. They may bee made to have a polar character of either a p-type or an n-type polycrystalline semiconductor through doping of an impurity to adjust the threshold values of the transistors. In addition, it does not matter if the bottom electrode 600 is included or not.

The above-described p+-type semiconductor regions 602 and 604, the intrinsic polycrystalline semiconductor region 608 and the gate 603 form together a p-type transistor that is a TFT. Also, the above-described n+-type semiconductor regions 605 and 607, the intrinsic polycrystalline semiconductor region 609 and the gate 606 form together an n-type transistor that is a TFT.

The gates 603 and 606 are electrically connected while the p+-type semiconductor region 604 and the n+-type semiconductor region 605 are electrically connected. The p+-type semiconductor region 602 is connected to the power source (VDD) and the n+-type semiconductor region 607 is grounded to the VSS. Furthermore, the bottom electrode 600 is grounded to the VSS. The inverter circuit 110 shown in FIG. 1 is formed by these connections.

It does not matter if the bottom electrode 600 is not grounded to the VSS.

The current consumption of the oscillation circuit can be reduced if TFTs having the above-described structure are used to form the oscillation circuit shown in FIG. 1 and the drain terminal capacitance (Cd) 103 is made smaller than the gate terminal capacitance (Cg) 102.

In the present embodiment, as well, at least one of the drain terminal capacitance (Cd) 103 and the gate terminal capacitance (Cg) 102 may be a voltage variable capacitance. In this case, the current consumption can be controlled if the voltage applied to the voltage variable capacitance is controlled to vary the capacitance value.

Meanwhile, in the first and the second embodiments, the p-type transistor 100, the n-type transistor 101 and the feedback resistance (Rf) 104 can be formed on the same SOI substrate to be made into an integrated circuit. In this case, the drain terminal capacitance (Cd) 103, the gate terminal capacitance (Cg) 102 and the quartz crystal resonator 105 are connected outside the integrated circuit. Alternatively, the drain terminal capacitance (Cd) 103 and the gate terminal capacitance (Cg) 102 may be integrated on the same SOI substrate as that of the above-described transistors.

The oscillation circuit according to the embodiments of the invention has been specified in the above, but the concrete structure of the oscillation circuit is not limited to the above-described embodiments. Modifications of the design and other factors are also included in the invention, insofar as they do not deviate from the intent and spirit of the invention.

For example, the inverter circuit has been described as only one that is included in the oscillation circuit, but a plurality of inverter circuits may be included therein.

In addition, transistors having a structure other than the structures described above may be used as well.

The entire disclosure of Japanese Patent Application Nos: 2006-286165, filed Oct. 20, 2006 is expressly incorporated by reference herein.

What is claimed is:

1. An oscillation circuit comprising:
an inverter circuit composed of at least one pair of transistors including an n-type transistor and a p-type transistor, the inverter circuit being formed in a single crystal semiconductor layer deposited on an insulator;
a gate terminal capacitance whose one end is connected to an input end of the inverter circuit and other end is grounded;
a drain terminal capacitance whose one end is connected to an output end of the inverter circuit and other end is grounded; and
a feedback resistance and a resonator that are connected in parallel between the input end, and the output end of the inverter circuit, the drain terminal capacitance having a capacitance value that is smaller than the capacitance value of the gate terminal capacitance.

2. The oscillation circuit according to claim 1, wherein the n-type transistor and the p-type transistor are field effect transistors.

3. The oscillation circuit according to claim 1, wherein the n-type transistor and the p-type transistor are thin film transistors (TFTs).

4. The oscillation circuit according to claim 1, wherein at least one of the drain terminal capacitance and the gate terminal capacitance is a voltage variable capacitance.
